(19) United States
(12) Patent Application Publication
(10) Pub. No.: US 2012/0228275 A1
(43) Pub. Date: Sep. 13, 2012

(54) METHOD FOR EXPOSING AN ELECTRICAL CONTACT

(75) Inventors: Axel Heinrici, Aachen (DE); Günter Neumann, Aachen (DE); Lars-Soeren Ott, Dueren (DE)

(73) Assignee: REIS GROUP HOLDING GMBH & CO. KG, Obernburg (DE)

(21) Appl. No.: 13/381,489

(22) PCT Filed: Jun. 29, 2010
(86) PCT No.: PCT/EP2010/059167

§ 371 Date: Mar. 19, 2012

(30) Foreign Application Priority Data
Jun. 29, 2009 (DE) 10 2009 026 064.1
Sep. 16, 2009 (DE) 10 2009 044 022.4

(51) Int. Cl. B23K 26/00

(52) U.S. Cl. 219/121.72

(57) ABSTRACT

A method for exposing at least one electrical contact, which is covered by at least one layer made of plastic, by means of a laser beam. In order to allow the targeted and reproducible exposing of the electrical contact in an automated process, the location of the at least one electrical contact is determined by means of a sensor, and the at least one layer made of plastic is removed in a flat area, in consideration of the determined location of the electrical contact and according to a pattern stored in a controller of a laser scanner, the projection of said flat area being inside of the contact in the direction of the contact.

The invention relates to a method for exposing at least one electrical contact of a solar cell or of a solar cell module, which contact is covered by at least one layer preferably consisting of plastic.

An apparatus for removing layers on a workpiece by a laser beam can be gathered from DE-B-199 64 443 that has a trapezoidal beam profile on the surface to be worked. Potential workpieces are also thin-layer solar cells in which in order to contact the electrode on the back side, layers located above it are selectively removed. A pulsed laser of the Nd:YAG type is used as laser, which is operated with the quality modulation method with pulse times in the range of 25 μs.

A method for producing a solar cell is known from DE-A-10 2007 011 749 in which a transparent dielectric layer is locally removed by an ultrasonic short-pulse laser.

In order to produce a breakthrough in a dielectric layer consisting of a polymer for exposing an electrical contact, a laser beam is used in accordance with EP-A-0 388 009.

A method for repairing a line of a thin-film image sensor is known from U.S. Pat. No. 5,480,812 (EP-B 0 685 113). In it, a non-conductive layer can be removed in the repair area by a laser.

The subject matter of EP-A-0 649 045 is a method for repairing interruptions of a liquid crystal substrate. For this, a medium is applied onto the interrupted area and melted by laser in order to repair the connection.

In order to treat surfaces of, e.g., workpieces, a removable of surfaces takes place with a laser beam in accordance with DE-A-199 00 110.

An apparatus for observing areas that are being repaired by laser beam can be gathered from JP-A-2004 066 344.

In order to remove burrs on housing sides in order that electronic structural elements are exposed, DE-A-103 13 521 provides that the burrs are removed by laser beam. The appropriate areas are detected with an image recognition- and processing system.

Holes are formed with a CO₂ laser in accordance with EP-A-884 128 in a layer consisting of plastic in order to make possible connections to a printed circuit.

According to the prior art, it is necessary in the production of photovoltaic modules to unthread the interconnection bands or cross connectors to the outside contacting prior to the lamination of the modules out of the transparent plastic layer covering the back side, which layer can consist of ethylene vinyl acetate (EVA) or silicon rubber, in order to connect the bands to the connections of a contact box. The necessary recesses in the plastic layer as well as the compound plastic foil covering this layer on the back side and consisting, e.g., of polyvinyl fluoride and polyester, are formed, for example, by punching. However, an additional, usually manual intervention prior to the lamination is required for the unthreading of the cross connectors.

Defective electrical connections not only result in that the degree of effectiveness of the modules is degraded but there is also the danger due to so-called hot spots that a development of heat is produced that can start a fire.

If it is determined during the production that an orderly wiring between the individual strings of the module did not take place, the latter is rejected.

The present invention has the task, among other things, of further developing a method of the initially cited type in such a manner that in an automated process a targeted and reproducible exposing of an electrical contact is made possible in order to make possible a desired, electrically conductive connection to connections in particular in subsequent processings. At the same time, it should be ensured that a damaging of the material surrounding the contact is avoided during the exposing of the electrical contact. According to another aspect several electrical contacts covered by at least one layer consisting of plastic are to be exposed in defined areas in order to be able to connect them simultaneously in an automated manner to other contacts. In particular, the possibility should also be created of wiring a solar cell module to a connection box in an automated process.

The invention also has the aspect that a repairing of defective electrical contacts is made possible with simple measures so that in particular defective solar cell modules can be further used or reused.

The invention essentially provides for the solution of the task and/or aspects:
the determination of the position of the at least one contact by a sensor,
the removal of the at least one layer with a laser beam of a laser scanner, taking into account the determined position and a pattern filed in a control of the laser scanner,
   whereby the at least one layer is removed in a flat area the projection of which lies in the direction of the contact inside or substantially inside the latter.

The removal of the layer in an area whose projection is located in the direction of the contact inside the latter signifies here that the area of the layer that directly borders the contact is located inside or substantially inside the projection in the direction of the contact. However, an area can also be removed in the surface area of the layer to be removed that is also located outside of the projection in the direction of the contact so that so that a funnel-shaped exposure in the direction of the bottom results. This is advantageous for the contacting to be carried out and for the case that the contact is to be repaired.

The feature “substantially inside the contact” is intended to express that the invention is not departed from even if layer material located at the side of the contact is also removed in the immediate area of the contact. However, it should be ensured that the laser beam used for the removal is not inserted into the glass disk that extends over the solar cells to be wired and runs on the entrance side of the light beam.

Thus, the invention is distinguished in particular in that material is removed starting from the surface of the at least one layer to be removed in the direction of the contact in such a manner that a funnel-shaped opening results in the at least one layer, whereby the projection of the opening lies in the area of the surface in the direction of the contact in areas outside of the latter and the projection of the opening impinging upon the contact lies inside or substantially inside the contact.

The invention also includes in particular the fact that the laser beam removes an area of the layer immediately above the contact, the projection of which lies in the direction of the contact exclusively inside the contact.

It is provided in particular that several electrical contacts in the form of cross connectors of a laminated solar cell module are exposed and are connected to contacts of a connection box, whereby the cross connectors are covered on the back side of the solar cell module by a transparent plastic layer and by a plastic foil and that the plastic layer and the plastic foil are removed by the laser beam.

Furthermore, the invention provides that the electrical contact is a defective contact that is repaired or renewed after the removal of the at least one layer.

Therefore, in order to solve an aspect of the invention, it is suggested that the position of the at least one electrical contact is determined by a sensor and that the at least one layer of plastic is removed in a flat area whose projection lies in the direction of the contact within the latter, taking into account the determined position of the electrical contact in accordance with a pattern filed in a control of a laser scanner.

In order to solve the task of another aspect, substantially the following method steps are suggested:
Determination of the position of the contact to be repaired by a sensor,
the removal of the at least one layer with a laser beam of a laser scanner, taking into account the determined position and a pattern filed in a control of the laser scanner, and
the repairing or renewal of the electrical contact.

According to the invention a method for a laser-based removal of at least one plastic layer is suggested, whereby an automation is given that leads to reproducible results and at the same time ensures that the at least one electrical contact is exposed exclusively in the area in which the contacting to another contact should take place.

In order to wire solar cell modules in which contacts are to be exposed, the cross wiring bands are not exposed until after the lamination, as a result of which the foils are not partially open before the lamination and the cross wiring bands can be unthreaded through the latter. This avoids liquefied EVA material from exiting out of the open area and thus contaminating and damaging the membrane of the laminator.

In particular, an optical sensor with image processing is used as sensor, so that the data of the position of the at least one electrical contact preferably determined in the transillumination method is transmitted to the control of the laser scanner and the latter can expose the area or areas in the electrical contact in accordance with the pattern filed in the control. The laser scanner used can be one with a two-axis scanning system preferably with a plane field lens or a three-axis scanning system with fixed focal length can be used.

“Patterns” signifies here and/or includes how the laser beam is moved to the contact to be exposed or repaired. However, patterns can also include laser performance, width of the laser beam impinging on the layer to be removed or other parameters required for the application of the laser beam.

Due to the absorption and transmission qualities of the foil materials used, a CO₂ laser system is preferably used. Either a cw laser can be used or, however, a pulsed laser system. In the latter instance the work is preferably performed with a pulse frequency greater than 5 kHz, in particular greater than 10 kHz, so that a quasi-continuous operation results.

The maximum process rate is directly dependent on the laser performance. In order to remove the at least one layer consisting of plastic the laser beam should be moved over the area to be removed at a rate between 200 mm/sec, preferably between 3300 mm/sec and 3700 mm/sec.

For a radiation source of 300 W a favorable range is in particular between 3300 mm/sec and 4500 mm/sec. However, in the case of very high available laser performances even higher process rates can be realized.

The direction of the movement of the laser beam itself can be as desired. Preferably, however, a meandering or zigzag movement can be carried out. This has the advantage that the areas are uniformly loaded with the laser beam so that undesired heat formations are excluded that could result in damage.

Independently of the above, the energy of the laser beam should be adjusted in such a manner that the area to be removed is traveled over several times, in particular two to five times, as a result of which especially protective sublimation, that is, evaporation of the layer consisting of plastic takes place without damage to the electrical contact or to the areas running around it.

A reproducible removal also results if the laser beam is moved over the surface to be removed along lines running parallel to each other, whereby the distance between the lines should be less than the focal diameter of the laser beam imaged on the surface.

If the movement takes place in such a manner that a reversal of movement takes place in the edge area with simultaneous halting of the mirrors of the laser scanner that are guiding the laser beam, the laser is cut out at the reversal point so that an undesired development of heat is avoided. Braking effects/acceleration effects of the mirrors of the laser scanner are not noticeable in this instance, so that a uniform, i.e., homogenous removal is ensured.

The laser beam itself should be imaged in a punctiform manner on the surface to be removed with a diameter between 0.3 mm and 1.2 mm, in particular between 0.4 mm and 0.8 mm. If a smaller focus is used, a higher process rate can be achieved.

In order to achieve an economical removal rate the laser should be operated at least with a performance P of 100 watts≦P≦1000 watts. Higher performances are possible and allow higher process rates but require significantly higher investment costs.

The optical sensor for the image processing for detecting the position of the electrical contact should run, relative to the laser scanner, on the opposite side, whereby the measuring can be performed with the transillumination method.

The invention is distinguished in particular by a method for the exposing of cross connectors of a laminated solar cell module that are to be connected by contact with a connection box, whereby the cross connectors are covered on the solar cell module side by a transparent layer of plastic consisting in particular of ethylene vinyl acetate (EVA) or silicon rubber as well as a plastic foil that preferably contains polyvinyl and polyester.

The method in accordance with the invention is suited not only for exposing contacts in order to connect them to contacts of a connection box. Even the exposing of cross connectors of a laminated solar cell module that are to be connected to at least one cell connector or string connector is possible on account of the teaching of the invention.

It turned out that the method of the invention is superbly suited for exposing on a laser basis areas of electrical contacts such as cross connectors of photovoltaic modules, that is, e.g., for subsequently introducing recesses after the lamination in order to then make possible an automatic connecting to external contacts such as the contacts of a connection box or to repair or renew defective contacts. An automatization takes place here in such a manner that the position of the electrical contacts is detected by, e.g., an image processing or some other suitable sensor, the positional data is supplied to the control of a laser scanner and then conducted as a function of a stored pattern of the laser beams via the electrical contacts so that the layers covering the latter are removed by vaporization.

The laser beam can be controlled in such a manner that exclusively or substantially exclusively areas above the electrical contact are exposed so that damage to other areas and in particular an introduction of energy outside of the electrical contact can not take place to such an extent that it could result in that the glass covering the solar cell module on the front side bursts.

In particular, it is provided that the exposed area or areas are metallurgically connected by soldering such as laser soldering, induction soldering or contact soldering.

In the case of the exposing of cross connectors in order to connect them to contacts of a connection box, a further development provides that after the exposing of the cross connectors the solar cell module is supplied to a processing station in which the contacts of the connection box are placed on the exposed areas of the cross connectors by a manipulating device and they are then connected to the exposed areas in a non-positive manner and/or metallurgically. The processing station can also be the one in which the contacts are exposed.

In particular, it is provided that the exposed areas are metallurgically connected by soldering such as laser soldering, induction soldering or contact soldering.

During the electrically conductive connecting of the exposed areas to the contacts or afterwards the connection box is then connected to the solar cell module preferably by silicon or adhesive tape.

In order to align the contacts of the connection box in the precise position on the exposed areas of the cross connectors, it is provided that the position of the solar cell module with the exposed areas is determined by an image processing and the data obtained in this manner is transmitted to the control of the manipulating device. This ensures an unobjectionable electrical contact. The detection of position can be eliminated if the exposure of the cross connector and the setting of the connection box take place in the same processing station.

Further details, advantages and features of the invention result not only from the claims, the features to be gathered from them—alone and/or in combination—but also from the following description of preferred exemplary embodiments to be gathered from the drawings,

In which:

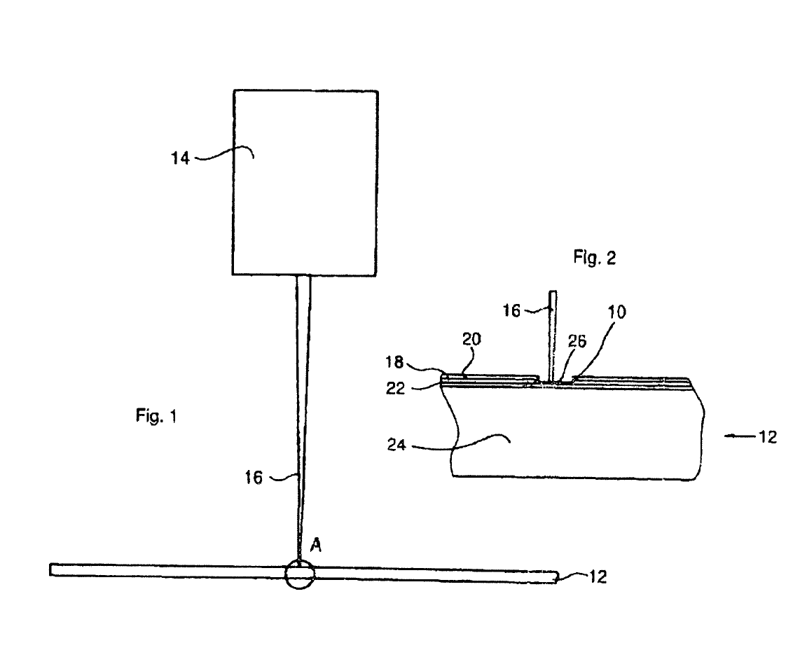

FIG. 1 shows a basic view of an arrangement for removing a layer of plastic covering an electrical contact,

FIG. 2 shows a detail “A” from FIG. 1,

FIG. 3 shows a section of a solar cell module,

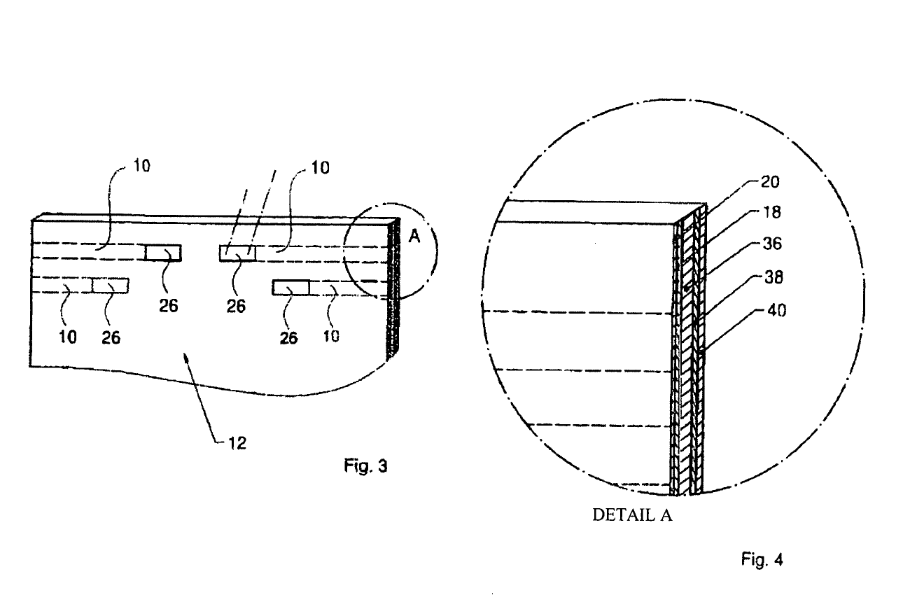

FIG. 4 shows a detail “A” from FIG. 3,

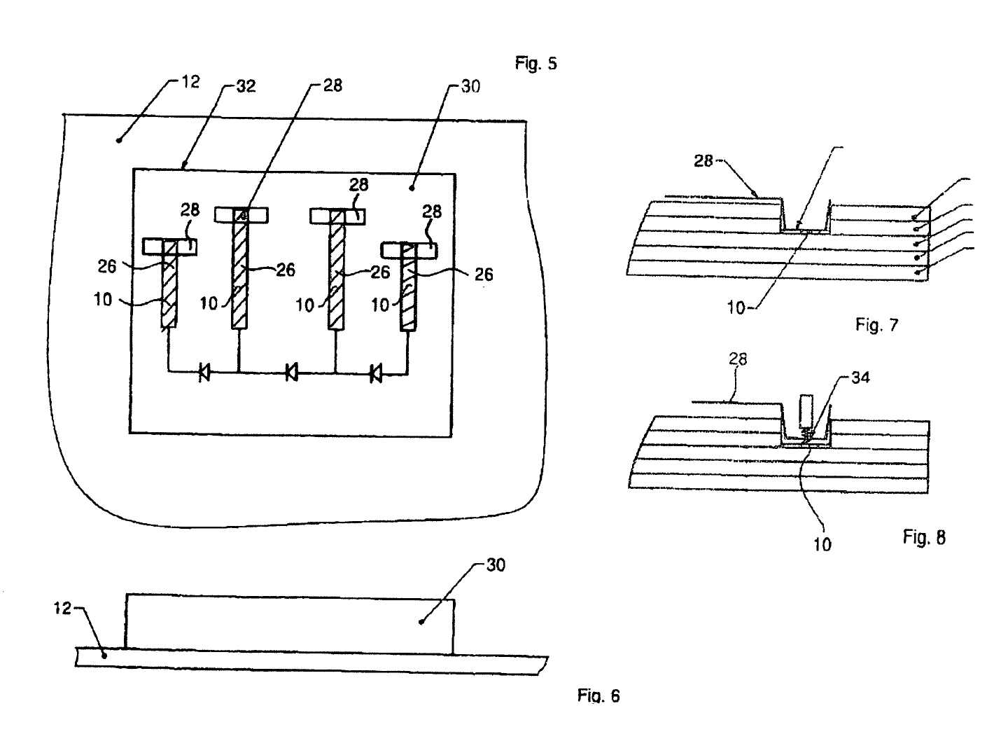

FIG. 5 shows a basic view of a wiring of cross connectors of a solar cell module with contacts of a connection box,

FIG. 6 shows the arrangement according to FIG. 5 in a lateral view,

FIG. 7 shows a first embodiment of a contact of a connection box with a cross connector,

FIG. 8 shows a second embodiment of a contact of a connection box with a cross connector,

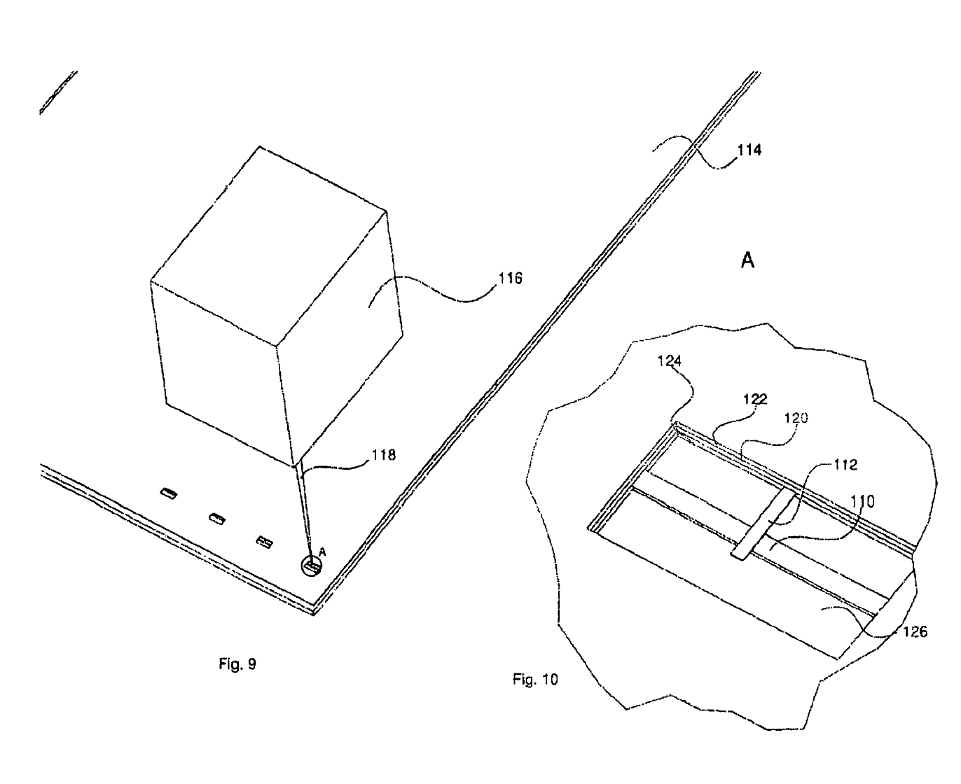

FIG. 9 shows a basic view of another arrangement for removing a layer of plastic covering an electrical contact, and

FIG. 10 shows a detail “A” from FIG. 9.

In the FIGS. 1 to 8 the teaching of the invention for exposing at least one electrically conductive contact that is covered by at least one layer consisting of plastic is described using a solar cell module without this being intended to limit the teaching of the invention. In the figures basically the same reference numerals are used for the same elements.

FIG. 1 shows a purely basic arrangement with which a cross connector 10 of a solar cell module 12 is exposed in order to then be connected in an electrically conductive manner to connection contacts of a contact box.

To this end a laser scanner 14 is provided that comprises, in addition to a laser such as a CO₂ laser that emits laser irradiation, deflection mirrors and lenses in order to move the laser beam 16 over a desired area of the solar cell module 12 in order to remove layers 18, 20 covering the cross connector 10 by vaporization. A laser scanner is used whose construction and operation is sufficiently known to an average person skilled in the art.

According to the exemplary embodiment of the solar cell module 12 this concerns in the case of the layers 18, 20 a transparent layer of plastic consisting of, e.g., ethylene vinyl acetate (EVA) or silicon rubber running on the cross connector side and concerns a weatherproof composite plastic foil of, in particular, polyvinyl fluoride and polyester covering the latter on the outside.

Another transparent layer of plastic consisting of, e.g., ethylene vinyl acetate (EVA) or silicon rubber and characterized with 22 runs in the area of the cross connectors 10 underneath the latter. The corresponding unit is arranged on a glass plate 24 or some other transparent carrier. The wired solar cells themselves, that are located between th layers 20 and 22, are not shown.

After the arranging of the individual layers and of the solar cells the lamination of the module takes place in particular at temperatures of approximately 150° C. and in a vacuum. During the lamination a clear plastic layer forms out of the originally milky transparent plastic layers (EVA or silicone rubber) directly surrounding the solar cell in which clear plastic layer the solar cells are embedded and permanently connected to the glass disk or to the foil on the rear side. However, to this extent sufficiently known techniques are referred to.

In order to connect the cross connectors 10 to the connection contacts of a connection box the laser beam 16 is moved according to a given pattern in the areas 26 to be exposed which pattern is filed in the control of the laser scanner 14. An energy input takes place here to an extent such that the layers 10, 20 running above the cross connectors 10 volatilize without any damage occurring to the surroundings, i.e., to the adjacent area of the solar cell module 12. In particular, it is avoided that the laser beam 16 impinges next to the cross connector 26 upon the layers 18, 20 to such an extent that an insertion into the glass plate 24 occurs with the consequence that the latter bursts.

The movement of the laser beam 16 can take place in a meandering or zigzag or linear manner along parallel straight lines. However, it is essential that a uniform removal, that is, a uniform volatilization of the layers 18, 20 takes place above the cross connector 26. Therefore, a delay for the switching on of the laser is provided for the case that the mirrors or mirror of the laser scanner 14 are stopped.

This means that during a standstill of the mirror or mirrors laser light does not impinge upon the module, therefore, the laser is turned off.

The distance of the laser lines can be varied, whereby an overlapping of the laser lines occurs. In particular, the laser can be moved over the area to be removed in such a manner that the distance of the laser lines is in a range between 0.05 mm and 0.2 mm, preferably in a range between 0.1 mm and 0.2 mm. Thus, a sufficient overlapping is given since the diameter of the focus is greater than 0.1, in particular in a range between 0.4 mm and 1.0 mm.

The laser system preferably comprises a CO₂ laser with a two-axis scanning system. In order to image the focus in a straight plane over the entire surface to be removed, an appropriate plane field lens is provided. However, a three-axis scanning system with a fixed focal length can also be used.

Independently of the above, the CO₂ laser should operate with a maximum scanning ratio of 50%, whereby the pulse widths should be between 10 μ/sec and 400 μ/sec.

The speed at which the laser beam travels over the area to be removed should be in a range between 1000 mm/sec and 4000 mm/sec, whereby especially uniform results can be achieved if the area to be removed is multiply traveled over by the laser beam. Speed, laser performance and pulse frequency should therefore be coordinated in such a manner that a double to triple traveling over is possible. A quasi-continuous operation should especially preferably be adjusted so that pulse frequencies of more than 10 kHz are to be preferred.

Furthermore, it is provided that the surface removal rate is between 75 mm²/sec and 225 mm²/sec at a thickness of the layers 18, 20 to be removed of between 0.5 mm and 1 mm.

FIGS. 5 and 6 are intended to illustrate that appropriate cross connectors 10 of the solar cell module 12 that are exposed in accordance with the invention are subsequently contacted to connection contacts 28 of a connection box 30 which for their part are connected to the solar cell module, i.e., its laminate, e.g., by silicon or adhesive tape. This should basically be made clear by the border in FIG. 6 characterized by reference numeral 32.

The solar cell module 12 with the exposed cross connectors 10 is previously measured by an image processing system or some other sensor such as is explained in conjunction with the FIGS. 9 and 10 in order to then supply the position data to the control of a manipulating device by means of which the connection box 30 is aligned in the exact position with its contacts 28 onto the cross connectors 10 in order to then establish the required electrical contact. Two contacting possibilities for this are shown in FIG. 7. In FIG. 7 the first connector 10 is connected metallurgically to the connection contact 28 of the connection box 30. This takes place in particular by laser welding or induction welding. According to the exemplary embodiment of FIG. 8 the connection contact 28 to the cross connector 10 is alternatively established via a spring contact 34. Other connection types are of course equally possible.

As follows from the FIGS. 3 and 4, the layers 18, 20 are exposed in several areas on the rear side, namely, everywhere that cross connectors run, that then are to be connected with connection contact in an electrically conductive manner to connection box.

FIG. 3 shows by way of example four corresponding, exposed areas 26 of cross connectors 10.

Furthermore, the basic construction of a solar cell module follows once again from FIGS. 3 and 4. The corresponding layer construction can be gathered in detail from FIG. 4.

The solar cell module 12 is viewed from the rear so that the weatherproof composite plastic foil consisting, e.g., of polyvinyl fluoride and polyester (layer 20) can be recognized, then the layer 18 consisting, e.g., of ethylene vinyl acetate or silicon rubber, basic solar cells 36, another layer 38 consisting of transparent plastic of, e.g., ethylene vinyl acetate or silicon rubber and finally a glass layer 40 on the front side. Then, the cross connectors 10 eminate from the solar cells 36 wired in series or in parallel which cross connectors are connected to the contacts 28 of the connection box 30.

According to the invention a laser-based removal of the rear layers 18, 20 of the laminated solar cell module 12 takes place in the areas of the cross connectors 10 that are to be connected to the contacts 28 of the connection box 30. A reproducible, fully automatic exposure of the cross connectors 10 takes place without damaging the bordering areas of the solar cell module 12.

High surface removal rates can be achieved that are readily in the range between 150 mm²/sec and 200 mm²/sec in customary rear layer thicknesses, whose thicknesses can be on the whole between 0.5 mm and 1 mm.

The precise detection of the position of the cross connectors 10 by, e.g., image processing ensures that the laser beam exclusively loads selective areas of the layers 18, 20 to be removed. An insertion of the laser irradiation into areas adjacent to the cross connector 10 so that an insertion into the glass 40 takes place can therefore be excluded, which glass could otherwise shatter. The cross connectors 10 are exposed to such an extent that a reliable metallurgical connection to the connection contacts 28 of the connection box 30 takes place.

Even if it should basically be prevented that material present in the area of the contact is removed, that is, loaded by the laser irradiation, which material runs adjacent to the cross connector 10, in order to exclude an insertion of the laser irradiation into the glass 40, the invention is not departed from if a removal of material takes place in the upper area of the at least external layer 20, if necessary also to the upper area of the layer 18 which removal of material has an areal extension whose projection runs in the direction of the contact laterally adjacent to the contact so that an area quasi-exposed in funnel shape or in a trapezoidal shape in section extends starting from the surface of the layer to the contact. This measure achieves the advantage that the connecting to the connection contacts 28 is simplified.

The same exposure that is funnel-shaped or trapezoidal in section can also be carried out if, e.g., contacts are to be repaired, as is explained in conjunction with the FIGS. 9 and 10.

Another aspect of the teaching of the invention is to be explained using the FIGS. 9 and 10, on the basis of which a defective electrical contact can be repaired or renewed. At the same time the teaching is also explained using a solar cell module without that this should limit the teaching of the invention. Likewise, basically the same reference numerals are used for the same elements.

Independently of the above, refer to the explanations that were given in conjunction with the FIGS. 1 and 8 as regards the laser system and the laser used, the parameters with which the laser system is operated, or the type and extent of the removal of the surface of the at least one layer consisting of plastic that is located above the contact.

FIG. 9 shows a basic arrangement with which an electrical contact between a cross connector 110 and a cell connector or string connector 112 of a solar cell module 114 is exposed in order to reconnect it then in a conductive manner.

A laser scanner 116 is used for the exposing that comprises, in addition to a laser such as a CO₂ laser that emits a laser irradiation, deflection mirrors and lenses in order to move the laser beam 118 over a desired area of the solar cell module 114 in order to remove by volatilization the layers 120, 122 covering the cross connector 110 and the cell connector 112. A laser scanner is used whose construction and operation is sufficiently known to an average person skilled in the art.

In accordance with the exemplary embodiment of the solar cell module 114, the layers 120, 122 are a transparent layer of plastic running on the cross connector side and consisting, e.g., of ethylene vinyl acetate (EVA) or silicon rubber, and a weatherproof composite plastic foil consisting in particular of polyvinyl fluoride (TEDLAR) and polyester covering it on the outside.

Another transparent plastic layer of, e.g., ethylene vinyl acetate or silicon rubber characterized by 124 runs in the area of the cross connector 110 below it. The corresponding unit is arranged on a glass plate 126 or on some other transparent carrier. The wired solar cells themselves that are present between the layers 120 and 124 are not shown.

After the completion of the module an operational testing takes place. If it should be determined that defects in the wiring or that electrically conductive contacts with insufficient quality are present between the cross connectors and the string- or cell connectors, then the module is separated out in accordance with the prior art, since otherwise the danger of an inadmissible heating during operation increases until the production of a fire.

Based on the teaching of the invention, a checking of the module takes place that determines which electrical contact(s) is/are defective. This can take place with an image processing as sensor. However, defective contact spots can also be determined by temperature sensors.

If the defective contacts have been determined, then the laser beam 118 is moved according to a given pattern, filed in the control of the laser scanner 116, over the area or areas to be exposed. An introduction of energy takes place to such an extent that the layers 120, 122 running above the cross connector 110 and above the string connector or string connectors 112 volatilize.

“Pattern” signifies and/or includes here how the laser beam is moved to the contact to be repaired or which laser performance is used. Even the width of the laser beam impinging upon the layer to be removed or other parameters required for the application of the laser irradiation can include the concept “pattern”.

According to the invention, it is avoided that the laser beam can impinge outside of the contact to be repaired onto the layers 120, 122 to such an extent that an insertion into the glass plate 126 takes place. This can take place, e.g., by a template or via a placed exposing contour. An area is exposed for the irradiation by the latter that is smaller than that of the contacts to be repaired. “Exposing contour” signifies that the layer or layers covering the contact to be repaired are covered in the areas onto which the laser beam should not impinge. The areas in which a removal should take place for repairing the contact are left free.

The movement of the laser beam 118 can take place- as previously explained -in a meandering or zigzag or linear manner along straight lines running in parallel. However, it is essential here that a uniform removal, that is, the uniform volatilization of the layers 120, 122 above the contact position takes place. Therefore, a delay for the switching on of the laser is provided for the case that the mirrors or mirror of the laser scanner 116 are stopped.

This means that during a standstill of the mirror or mirrors laser light does not impinge upon the module 114, therefore, the laser 118 is turned off.

Refer to the explanations that were given in conjunction with the FIGS. 1 and 8 as regards the distance of the laser lines, their width, the type of the laser system used, scanning ratios and speed of type of the area to be traveled over. The same applies regarding the surface removal rate or other explanations made.

According to the invention a laser-based removal of the rear layers 120, 122 of the laminated solar cell module 114 takes place in the areas in which electrical contact connections are to be repaired. A reproducible, fully automatic exposure of the contact point takes place here.

High surface removal rates can be achieved that are readily in the range between 150 mm²/sec and 200 mm²/sec in customary rear layer thicknesses, whose thicknesses can be on the whole between 0.5 mm and 1 mm.

The precise detection of the position of the contact position by the sensor and image processing can ensure that the laser beam 118 exclusively loads the areas of the layers 118, 120 to be removed that run above the contact position. An insertion of the laser irradiation into the adjacent areas and therewith into the glass 126 is excluded, which glass could otherwise shatter. The contact position is exposed here to an extent that a reliable metallurgical connection takes place between the cross connector 110 and the cell- or string connector(s) 112.

1. A method for exposing at least one electrical contact of a solar cell or of a solar cell module, which contact is covered by at least one layer preferably consisting of plastic, characterized by the method steps
the determination of the position of the at least one contact by a sensor,
the removal of the at least one layer with a laser beam of a laser scanner, taking into account the determined position and a pattern filed in a control of the laser scanner,
whereby the at least one layer is removed in a flat area the projection of which lies in the direction of the contact inside or substantially inside the latter.

2. The method according to claim 1, characterized in
that several electrical contacts in the form of cross connectors of a laminated solar cell module are exposed and are connected to contacts of a connection box, whereby the cross connectors are covered on the back side of the solar cell module by a transparent plastic layer and by a plastic foil and that the plastic layer and the plastic foil are removed by the laser beam.

3. The method according to claim 1, characterized in
that the electrical contact is a defective contact that is repaired or renewed after the removal of the at least one layer.

4. The method according to claim 1, characterized in
that the area of the layer in which the contact is exposed remains uncovered by a template or an exposing contour.

5. The method according to claim 1, characterized in
that the laser scanner used is one with a two-axis scanning system preferably with a plane field lens or a three-axis scanning system is used.

6. The method according to claim 1 characterized in
that a CO₂ laser system is used.

7. The method according to claim 1 characterized in
that a pulsed laser system is used whose pulse frequency is ν with ν≧5 kHz, especially ν≧10 kHz.

8. The method according to claim 1 characterized in
that in order to remove the at least one layer consisting of plastic, the laser beam used for the removal is moved over the surface to be removed at a rate V, whereby 200 mm/sec≦V≦7500 mm/sec, in particular 2000 mm/sec≦V≦4000 mm/sec, preferably 3300 mm/sec≦V≦3700 mm/sec.

9. The method according to claim 1, characterized in
that in order to remove the at least one layer consisting of plastic, the laser beam is moved several times over the surface to be removed.

10. The method according to claim 1, characterized in
that in order to remove the at least one layer consisting of plastic, the laser beam is moved two to five times, in particular two to three times over the surface to be removed.

11. The method according to claim 1, characterized in
that the laser beam is moved in a meandering or zigzag manner over the surface to be removed.

12. The method according to claim 1, characterized in
that the laser beam is moved along lines running parallel to each other over the area to be removed, whereby the distance between the lines is 0.05 mm to 0.2 mm, in particular between 0.1 mm to 0.2 mm.

13. The method according to claim 1, characterized in
that the laser system is operated with a delayed cutting-in in the edge area of the surface to be removed.

14. The method according to claim 1, characterized in
that the laser system is operated in such a manner that the pulse widths are between 10 μ/sec and 400 μ/sec.

15. The method according to claim 1, characterized in
that the laser is operated in such a manner the removal rate is between 75 mm²/sec and 225 mm²/sec, preferably 100 mm²/sec and 200 mm²/sec at a layer thickness to be removed of between 0.5 mm and 1.0 mm.

16. The method according to claim 1, characterized in
that the laser beam is focused in a punctiform manner on the surface to be removed with a diameter D with 0.3 mm≦D≦1.2 mm, in particular 0.4 mm≦D≦0.8 mm.

17. The method according to claim 1, characterized in
that the laser system is operated with a performance P with 100 watts≦P≦1000 watts, in particular 200 watts≦P≦400 watts.

18. The method according to claim 1, characterized in
that an optical sensor with image processing is used as a sensor.

19. The method according to claim 1, characterized in
that a temperature-measuring sensor is used as a sensor.

20. The method according to claim 1, characterized in
that the optical sensor is positioned on the opposite side of the at least one electrical contact relative to the laser scanner.

21. The method according to claim 1, characterized in
that the position of the at least one electrical contact is determined optically with the transillumination method.

22. The method according to claim 1, characterized in
that the position of the at least one electrical contact is determined inductively.

23. The method according to claim 1, characterized in
that that the position of the at least one electrical contact is determined with ultrasound.

24. The method according to claim 1, characterized in
that the at least one electrical contact is strip-shaped and is sealed in its edge areas delimiting the exposed area by material of the at least one plastic layer melted by the laser beam.

25. The method according to claim 1, characterized in
that the exposed electrical contact is renewed by soldering such as laser soldering in its metallurgical connection.

26. The method according to claim 2, characterized in
that after the exposing of the cross connectors of the solar cell module, the contacts of the connection box are placed by a manipulating device on the exposed areas of the cross connectors and they are then connected to the exposed areas in a non-positive manner and/or metallurgically.

27. The method according to claim 2, characterized in
that during the electrically conductive connecting of the exposed areas to the contacts or afterwards, the connection box is connected to the solar cell module preferably by silicon or adhesive tape.

28. The method according to at claim 2, characterized in
that the position of the solar cell module with the exposed areas is determined by an image processing and the data obtained in this manner is transmitted to the control of a manipulating device for aligning the contacts onto the exposed areas.

29. The method according to claim 1, characterized in
that material is removed starting from the surface of the at least one layer to be removed in the direction of the contact in such a manner that a funnel-shaped opening results in the at least one layer, whereby the projection of the opening lies in the area of the surface in the direction of the contact in areas outside of the latter and the projection of the opening impinging upon the contact lies inside the contact.

30. The method according to claim 1, characterized in
that the laser beam removes an area of the layer immediately above the contact, whose projection in the direction of the contact lies exclusively inside the contact.
